(19) United States
(12) Patent Application Publication
(10) Pub. No.: US 2012/0161172 A1
(43) Pub. Date: Jun. 28, 2012

(54) DISPLAY DEVICE AND METHOD FOR MANUFACTURING THE SAME

(75) Inventors: Takahito Oyamada, Machida (JP); Toshihiro Yoshioka, Kawasaki (JP); Toshiharu Uchida, Yonezawa (JP)

(73) Assignee: PIONEER CORPORATION, Kanagawa (JP)

(21) Appl. No.: 13/378,232

(22) PCT Filed: Jul. 6, 2009
(86) PCT No.: PCT/JP2009/003120

§ 371 Date: Mar. 19, 2012

(51) Int. Cl. H01L 33/08; H01L 33/60

(52) U.S. Cl. 257/89; 438/29; 257/E33.072

(57) ABSTRACT

A display device capable of suppressing a reduction in color purity includes: a first resonator structure having an upper reflective member, a lower reflective member, and a light-emitting functional layer therebetween, the light-emitting functional layer including a red light-emitting layer which emits red light; a second resonator structure having an upper reflective member, a lower reflective member, and a light-emitting functional layer provided therebetween, the light-emitting functional layer including a blue light-emitting layer which emits blue light; and a third resonator structure having an part reflective member, a lower reflective member, and a light-emitting functional layer provided therebetween, the light-emitting functional layer including a green light-emitting layer which emits green light, wherein the red light-emitting layer is a common layer provided in each of the light-emitting functional layers of the first to third resonator structures.

### TECHNICAL FIELD

The present invention relates to a display device and a method for manufacturing the same.

### BACKGROUND ART

As a display device such as a display unit or an illuminating device, there has been known an EL display device utilizing a substance which self-emits light in the presence of an applied voltage due to an electroluminescence (EL) phenomenon. The EL display device forms pixels in a display area by thin-film EL light-emitting elements including light-emitting functional layers which are made of an organic material or an inorganic material and provided between upper electrodes and lower electrodes.

An EL light-emitting element can emit light of red (R), green (G), or blue (B) by selecting, for example, a material or a color filter thereof.

Therefore, it is possible to manufacture a display device capable of performing full-color display by arranging a number of EL light-emitting elements which emit lights of red (R), green (G), and blue (B) on a substrate.

Note however that fabricating a number of minute and thin-film EL light-emitting elements on a substrate is technically difficult, and a high level of film formation accuracy is required. As one countermeasure therefor, there has been known that respective light-emitting layers of a red light-emitting element and a green light-emitting element are formed by an ink jet method, and a light-emitting layer of a blue light-emitting element is formed by a vacuum vapor deposition method or the like (for example, see Patent Literature 1).

However, the light-emitting element disclosed in Patent Literature 1 has a bottom emission structure in which light generated in a light-emitting layer is emitted from a side of an anode and a substrate which are formed of a transparent material. If a blue light-emitting layer is stacked on a red light-emitting layer and a green light-emitting layer, color purity for red and green may possibly be reduced. In particular, in a pixel for emitting red light, color purity is easily reduced due to the mixing-in of blue, and if a mixed-in amount of blue is large, the color may become purple.

### CITATION LIST

### Patent Literature

Patent Literature 1: Japanese Patent No. 4062352

### SUMMARY OF INVENTION

### Technical Problem

That is, problems to be solved by the present invention include the above-described problem as an example. Thus, an example of an object of the present invention is to provide a display device capable of suppressing a reduction in color purity and a method for manufacturing the same.

### Solution to Problem

As described in claim 1, a display device of the present invention includes: a first resonator structure having an upper part reflective member, a lower part reflective member, and a light-emitting functional layer disposed between the upper part reflective member and the lower part reflective member, the light-emitting functional layer including a red light-emitting layer which emits red light; a second resonator structure having an upper part reflective member, a lower part reflective member, and a light-emitting functional layer disposed between the upper part reflective member and the lower part reflective member, the light-emitting functional layer including a blue light-emitting layer which emits blue light; and a third resonator structure having an upper part reflective member, a lower part reflective member, and a light-emitting functional layer disposed between the upper part reflective member and the lower part reflective member, the light-emitting functional layer including a green light-emitting layer which emits green light. The display device is characterized in that the red light-emitting layer is a common layer disposed in each of the light-emitting functional layers of the first to third resonator structures.

As described in claim 11, a method for manufacturing a display device of the present invention includes: a step of forming lower part reflective members of first, second, and third resonator structures; a step of forming a light-emitting functional layer including a red light-emitting layer, which emits red light, on the lower part reflective member of the first resonator structure; a step of forming a light-emitting functional layer including a blue light-emitting layer, which emits blue light, on the lower part reflective member of the second resonator structure; a step of forming a light-emitting functional layer including a green light-emitting layer, which emits green light, on the lower part reflective member of the third resonator structure; and a step of forming upper part reflective members of the first, second, and third resonator structures. The method for manufacturing a display device is characterized in that the blue light-emitting layer and the green light-emitting layer are formed in the second and third resonator structures by separately coating them with a coating method, and the red light-emitting layer is formed in the first to third resonator structures with a film formation method other than the coating method as common layers disposed in the light-emitting functional layers of the first to third resonator structures, respectively.

### BRIEF DESCRIPTION OF DRAWINGS

FIG. 1 is a vertical cross-sectional view of RGB light-emitting elements according to a preferred first embodiment of the present invention.

FIG. 2 is a plan view of the RGB light-emitting elements according to the preferred first embodiment of the present invention.

FIG. 3 is a hierarchy diagram of the above RGB light-emitting elements.

FIG. 4 is a diagram showing manufacturing steps of the above RGB light-emitting elements.

FIG. 5 is a diagram showing emission characteristics of blue light in the above RGB light-emitting elements.

FIG. 6 is a diagram showing color purity of blue light in the above RGB light-emitting elements.

FIG. 7 is a diagram showing emission characteristics of green light in the above RGB light-emitting elements.

FIG. 8 is a diagram showing color purity of green light in the above RGB light-emitting elements.

FIG. 9 is a hierarchy diagram of RGB light-emitting elements if a blue light-emitting layer is made to be a common layer, for example.

FIG. 10 is a diagram showing emission characteristics of red light if the above blue light-emitting layer is made to be a common layer.

FIG. 11 is a diagram showing color purity of red light if the above blue light-emitting layer is made to be a common layer.

### DESCRIPTION OF EMBODIMENTS

Hereinafter, a display device according to preferred embodiments of the present invention will be described in detail with reference to the accompanying drawings. Note however that the embodiments to be described below shall not be construed to limit the technical scope of the present invention.

### First Embodiment

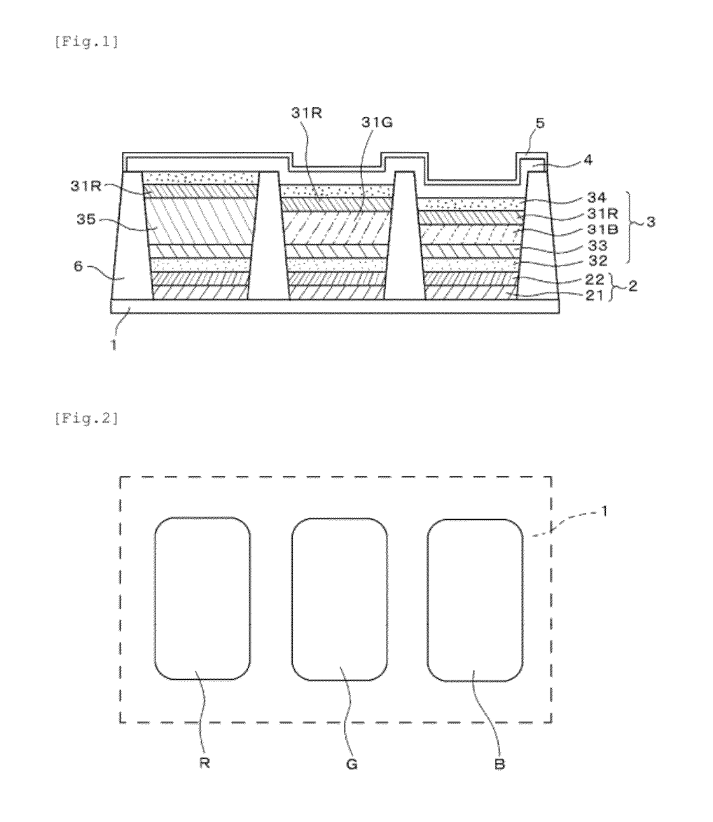

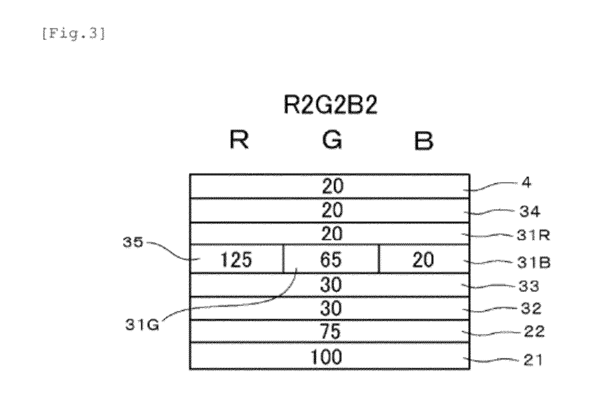

FIGS. 1 and 2 show an example where RGB light-emitting elements are formed by arranging first to third resonator structures (R, G, B), which respectively emit lights of red (R), green (G), and blue (B), on a common substrate 1. FIG. 1 is a vertical cross-sectional view of the RGB light-emitting elements, and FIG. 2 is a plan view thereof. FIG. 3 is a hierarchical structure diagram of the RGB light-emitting elements, and numerical values described in the hierarchical structure are examples of thicknesses of respective layers (film thicknesses). Note that the actual display device has a number of RGB light-emitting elements arranged on the substrate 1 to form a display area, and the RGB light-emitting elements are configured to be passively driven by a drive circuit which is not shown in the figure and disposed outside the display area or actively driven by arranging a drive circuit for each element.

As shown in FIG. 1, the first to third resonator structures (R, G, B) each have a so-called top emission structure in which an anode 2 as a lower part reflective member, a light-emitting functional layer 3, a cathode 4 as an upper part reflective member, and a sealing layer 5 are stacked on the substrate, and light emission is taken out from a surface side where the films are formed. These resonator structures (R, G, B) are partitioned by partition walls 6 called banks. Note that although not shown in the drawings, a film or a substrate for preventing the reflection of outside light may be further stacked. Moreover, the sealing layer 5 is an optional layer appropriately disposed, and there is a case where no sealing layer 5 is disposed.

The anode 2 has a two-layer structure having a reflective electrode 21 and a transparent electrode 22. As a material of the anode 2 to be in contact with the light-emitting functional layer 3, a material having a high work function is used. Specifically, as a material for the reflective electrode 21, a metal such as Al, Cr, Mo, Ni, Pt, Au, or Ag, an alloy or intermetallic compound containing these metals, or the like may be used, for example. A thickness of the reflective electrode 21 is 100 nm, for example. The reflective electrode 21 preferably has a high reflectance, for example, an average value of reflectances for light with a wavelength of 400 to 700 nm is 80% or more. Moreover, the transparent electrode 22 is an electrode made of a transparent material whose film thickness is adjusted so as to maximize the resonance effect thereof, for example. As a material for the transparent electrode 22, a metal oxide such as ITO (indium tin oxide) or IZO (indium zinc oxide), or the like, can be used, for example. A thickness of the transparent electrode is 75 nm, for example. Note that although FIGS. 1 and 2 omit the illustration thereof, an extraction electrode (wiring electrode) is connected to the anode 2. Note that the anode 2 may have a single-layer structure with the reflective electrode 21.

The first to third resonator structures (R, G, B) include the light-emitting functional layers 3 with a red light-emitting layer 31R which emits red light, a green light-emitting layer 31G which emits green light, and a blue light-emitting layer 31B which emits blue light. The red light-emitting layer 31R, the green light-emitting layer 31G, and the blue light-emitting layer 31B are EL light-emitting layers whose luminescent colors are differentiated by selecting materials generating an electroluminescence (EL) phenomenon, for example. Note however that the red light-emitting layer 31R is formed not only in the first resonator structure R but also in the respective light-emitting functional layers 3 of the second resonator structure G, and the third resonator structure B. That is, the red light-emitting layer 31R is a common layer formed in each of the light-emitting functional layers 3 of the first to third resonator structures (R, G, B) (it is therefore referred to also as a “red common layer” in the present specification).

The red common layers 31R are formed to have the same film thickness by simultaneously forming them with one step in the first to third resonator structures (R, G, B), for example. By employing the resonator structures, it is possible to suppress a reduction in blue and green color purity even if red light from the red common layer 31R is mixed in an amount of about 30% as will be described later in detail. Note however that a preferred film thickness of the red common layer 31R is 40 nm or less, and a more preferred film thickness is 30 nm in order to obtain color purity which reliably satisfies the standard for blue light and/or green light. Such a red common layer 31R can be formed by a method other than a coating method. Examples of the film formation method include a vapor deposition method and a laser ablation method. Note however that the film formation method is not limited thereto. Note that a mixed-in amount is based on an intensity ratio of emission peaks in R, G, and B, for example. It is in a range of 590 to 700 nm for R, 490 to 540 nm for G, and 430 to 490 nm for B.

Furthermore, as shown in FIG. 1, if the red light-emitting layers 31R are disposed so as to be in contact with the blue light-emitting layer 31B and the green light-emitting layer 31G, respectively, on a side of the cathode, it is preferable that the red light-emitting layers 31R have an electron transport property and/or a hole blocking property. The red light-emitting layer 31R having such a function can be formed by mixing a material having a light-emitting function to be described later with a material having an electron transport property or the like, also to be described later, for example.

On the other hand, the blue light-emitting layer 31B and the green light-emitting layer 31G are formed only in the second resonator structure G and the third resonator structure B. A film thickness of the blue light-emitting layer 31B is 20 nm, for example, and a film thickness of the green light-emitting layer is 65 nm, for example. Such a blue light-emitting layer 31B and green light-emitting layer 31G can be formed by separately coating these layers with a coating method such as an ink jet method, for example. Note however that the film formation method is not limited thereto.

It is only necessary for the light-emitting functional layers 3 disposed between the anodes 2 and the cathodes 4 to have at least EL light-emitting layers (31R, 31G, 31B). In order to efficiently facilitate an electroluminescence phenomenon, however, the light-emitting functional layer 3 preferably has a multilayer structure in which functional layers such as a hole injection layer and/or a hole transport layer, an electron transport layer and/or a hole blocking layer, and an electron injection layer are appropriately disposed.

In one example, FIG. 1 shows a configuration in which a hole injection layer 32, a hole transport layer 33, and an electron transport layer 34 are disposed. These hole injection layer 32, hole transport layer 33, and electron transport layer 34 are formed as common layers in each of the first to third resonator structures (R, G, B) as with the red common layer 31R. Therefore, the hole injection layers 32, the hole transport layers 33, and the electron transport layers 34 are formed with the same film thicknesses and in the same order. A film thickness of the hole injection layer 32 is 30 nm, for example; a film thickness of the hole transport layer 33 is 30 nm, for example; and a film thickness of the electron transport layer 34 is 20 nm, for example.

If the blue light-emitting layer 31B and the green light-emitting layer 31G are formed by a coating method such as an ink jet method, for example, it is preferred to select a material insoluble to these liquid materials or to perform insoluble treatment for the underlying hole transport layer 33 (alternatively, it may be a hole injection layer) to be in contact with the liquid materials. Although depending on the liquid material of a light-emitting layer, examples of a material insoluble for the above-described liquid materials include, among organic materials, DHTBOX in which a photothermal crosslinking type oxetane skeleton is introduced into a hole transport material (book: ORGANIC EL DEVICE PHYSICS•/MATERIAL CHEMISTRY•/DEVICE APPLICATION, see p. 112). Moreover, examples of the insoluble treatment include crosslinking treatment by a photopolymerization reaction or the like, a hydrophilizing treatment, and a hydrophobizing treatment.

The resonator structures (R, G, B) have resonator optical path lengths suitable for the respective luminescent colors. In a case of the structure shown in FIG. 1, a resonator optical path length corresponds to a separation distance between the reflective electrode 21 and a reflective surface of the cathode 4. As one example, a stacked film thickness to obtain a preferable resonator optical path length for red (R) is 300 nm, a stacked film thickness to obtain a preferable resonator optical path length for green (G) is 240 nm, and a stacked film thickness to obtain a preferable resonator optical path length for blue (B) is 195 nm. Note however that the stacked film thicknesses are not limited thereto.

As shown in FIGS. 1 and 3, resonator optical path lengths in the second resonator structure G and the third resonator structure B are adjusted by varying the thicknesses of the green light-emitting layer 31G and the blue light-emitting layer 31B which are EL light-emitting layers. Therefore, the other stacked films such as the hole injection layer 32 are common layers having the same thicknesses. On the other hand, in the first resonator structure R, since the red light-emitting layer 31R, which is an EL light-emitting layer, is a common layer, the resonator optical path length thereof is adjusted by newly adding an optical path length adjusting layer 35. By adding the optical path length adjusting layer 35, the other stacked films such as the hole injection layer 32 are common layers having the same film thicknesses as those of the stacked films in the second resonator structure G and the third resonator structure B.

The optical path length adjusting layer 35 can be disposed at a hierarchical position corresponding to the blue light-emitting layer 31B and the green light-emitting layer 31G using a material having a hole transport property (mobility) higher than that of the red light-emitting layer 31R. That is, the optical path length adjusting layer in FIG. 1 serves as a hole transport layer in addition to the function of adjusting the resonator optical path length. With the thus structure, there are obtained advantages such that the red light-emitting layer 31R can be formed thinner even in a resonator structure having the same order and it is possible to suppress a voltage increase in the first resonator structure R having the largest resonator optical path length. Note however that the position of the optical path length adjusting layer 35 is not limited to that shown in FIG. 1, and the optical path length adjusting layer 35 can be disposed at a position closer to the cathode side than the red light-emitting layer 31R by using a material with an electron mobility higher than that of the red light-emitting layer 31R.

For the hole injection layer 32, the hole transport layer 33, and the optical path length adjusting layer 35 in FIG. 1, it is only necessary that they are formed of a material having an excellent hole transport property (mobility). Examples of usable organic materials include a phthalocyanine compound such as copper phthalocyanine (CuPc), a starburst type amine such as m-MTDATA, a multimer of a benzidine type amine, an aromatic tertiary amine such as 4,4′-bis[N-(1-naphthyl)-N-phenylamino]-biphenyl (NPB) or N-phenyl-p-phenylenediamine (PPD), a stilbene compound such as 4-(di-P-tolylamino)-4′-[4-(di-P-tolylamino)styryl]stilbenzene, a triazole derivative, a styrylamine compound, and a fullerene such as a buckyball, C60, or DHTBOX in which an oxetane skeleton is introduced into a hole transport material. Alternatively, it is possible to use a polymer-dispersed material in which a low-molecular material is dispersed in a high-molecular material such as polycarbonate. Besides these, an oxide such as a molybdenum oxide, a tungsten oxide, a titanium oxide, or a vanadium oxide may be used. Note however that the materials are not limited thereto.

As the red light-emitting layer 31R, the green light-emitting layer 31G, and the blue light-emitting layer 31B, materials producing an electroluminescence (EL) phenomenon to emit lights of the respective colors are used. Examples of these materials include a fluorescent organometallic compound such as (8-hydroxyquinolinate)aluminum complex (Alq₃), a fluorescent organic material such as an aromatic dimethylidine compound such as 4,4′-bis(2,2′-diphenylvinyl)-biphenyl (DPVBi), a styrylbenzene compound such as 1,4-bis(2-methylstyryl)benzene, a triazole derivative such as 3-(4-biphenyl)-4-phenyl-5-t-butylphenyl-1,2,4-triazole (TAZ), an anthraquinone derivative, and a fluorenone derivative, a polymeric material of polyparaphenylene vinylene (PPV) base, polyfluorene base, or polyvinylcarbazole (PVK) base, and a phosphorescent organic material such as a platinum complex or an iridium complex. Note however that the materials are not limited thereto. They are not necessarily required to be organic materials, and inorganic materials producing an electroluminescence phenomenon may be used.

Examples of a preferred material for the red light-emitting layer 31R, which is a common layer, include 8-quinolinolato such as tris(8-quinolinolato)aluminum (Alq3), bis(8-quinolinolato)magnesium, bis[benzo(f)-8-quinolinolato]zinc, bis(2-methyl-8-quinolinolato)(4-phenyl-phenolate)aluminum, tris(8-quinolinolato)indium, tris(5-methyl-8-quinolinolato)aluminum (Balq), 8-quinolinolato lithium, tris(5-chloro-8-quinolinolato)gallium, or bis(5-chloro-8-quinolinolato) calcium, or a metal complex including at least one derivative thereof as a ligand, a phenanthroline derivative such as BCP or 2,9-bis(2-naphthyl)-4,7-diphenyl-1,10-phenanthroline (NBPhen), and an imidazole derivative such as 2,2′,2″-(1,3,5-benzenetriyl)tris(1-phenyl)-1H-benzimidazole (TPBI). Examples of a preferred material for imparting an electron transport property and/or a hole blocking property to the above-described red light-emitting layer 31R include Balq and TPBI. The blue light-emitting layer 31B and the green light-emitting layer 31G preferably include a material having a hole transport property or a bipolar transport property, and examples of such a material include 4,4′-Bis(carbazol-9-yl)biphenyl (CBP), 4,4′,4″-Tris(carbazol-9-yl)triphenylamine (TCTA), and an anthracene derivative. Moreover, a material having a bipolar transport property not only gives such a function to one material, but also can exert the function by mixing a material having a hole transport property with a material having an electron transport property. Examples of such a material configuration include a mixed configuration of TCTA and 2,6-bis(3-(9H-carbazol-9-yl)phenyl)pridine (26DCzPPy). By employing the red common layer 31R having a hole transport property or a bipolar transport property as described above, it is possible to efficiently generate an electroluminescence phenomenon in the green light-emitting layer 31G and the blue light-emitting layer 31B even if the red common layer 31R is disposed in each of the second and third resonator structures G and B.

It is only necessary that the electron transport layer 34 is formed of a material having an excellent electron transport property (mobility). Examples of a usable material include an organic material such as a silacyclopentadiene (silole) derivative such as PyPySPyPy, a nitro-substituted fluorenone derivative, and an anthraquinodimethane derivative, a metal complex of an 8-quinolinole derivative such as tris(8-hydroxyquinolinate)aluminum (Alq3), metal phthalocyanine, a triazole-based compound such as 3-(4-biphenyl)-5-(4-t-butylphenyl)-4-phenyl-1,2,4-triazole (TAZ), an oxadiazole-based compound such as 2-(4-biphenylyl)-5-(4-t-butyl)-1,3,4-oxadiazole (PBD), and a fullerene such as a buckyball, C60, or a carbon nanotube. Note however that the materials are not limited thereto.

As a material for the cathode 4, a material having a low work function in an area in contact with the electron transport layer 34 and having small reflection and transmission losses in the entire cathode can be used. Specifically, as a material for the cathode 4, a metal such as Al, Mg, Ag, Au, Ca, or Li or a compound thereof, or an alloy containing those can be used in a form of a single layer or layers stacked on top of another. Moreover, there may be a case where a thin lithium fluoride, lithium oxide, or the like is formed in the area in contact with the electron transport layer 34 so as to control the electron injection characteristics. The thickness of the cathode is 10 nm, for example. The present embodiment has a top emission structure in which light is outputted from the surface side where the films are formed, i.e., the cathode side. Therefore, the cathode 4 is a semi-transmissive electrode whose average value for transmittances for light with a wavelength of 400 to 700 nm is 20% or more, for example. The transmittance can be adjusted by a film thickness of the electrode, or the like, for example. Note that although the illustration thereof is omitted in FIGS. 1 and 2, an extraction electrode (wiring electrode) is connected to the cathode 4.

The sealing layer 5 can be formed of a transparent inorganic material having a small moisture vapor or oxygen transmittance, for example. Examples of a usable material for the sealing layer 5 include silicon nitride (SiN x), silicon oxynitride (SiOxNy), aluminum oxide (AlOx), aluminum nitride (AlNx), and the like.

An example of a usable material for the partition wall 6 called bank is a photosensitive resin containing a fluorine component. By containing a fluorine component, a liquid-repellency against a liquid material can be exerted. Therefore, it is possible to suppress liquid flow (what is called overlap) in a case where a film is formed by a coating method. The partition wall 6 is preferably formed of a material having a light shielding property.

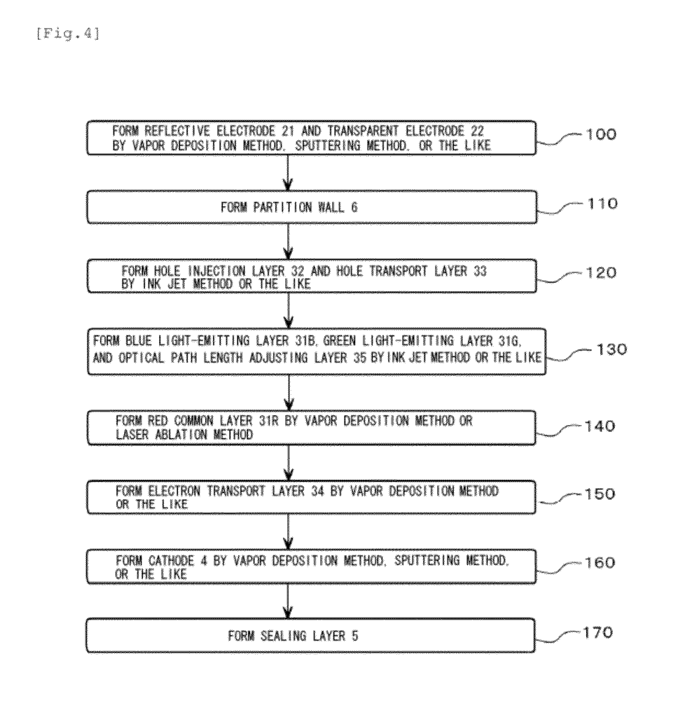

Next, with reference to a process chart of FIG. 4, steps for manufacturing the above-described RGB light-emitting elements will be described.

First, as shown in step 100 in FIG. 4, the reflective electrode 21 and the transparent electrode 22 are sequentially formed using vapor deposition, a sputtering method, or the like, for example. The patterning of these electrodes 21 and 22 can be performed by a photolithography method, for example. Next, as shown in step 110 in FIG. 4, a photosensitive resin containing a fluorine component, for example, is applied on the substrate 1 and dried to form a film. Thereafter, by using a photolithography method, for example, the partition walls 6 having the pattern as shown in FIG. 1 are formed. For example, in a case of a passive type, after the electrodes 21 and 22 are formed in a stripe shape, the partition walls 6 are formed. On the other hand, in a case of an active type, for example, after the electrodes 21 and 22 are formed in an island shape connected for each drive circuit, the partition walls 6 are formed.

Next, as shown in step 120 in FIG. 4, a liquid material for the hole injection layer 32 is applied within areas where the respective resonator structures (R, G, B) are formed, which are partitioned by the partition walls 6, by using an ink jet nozzle or the like, for example, and heated or irradiated with light to form films. It is preferable that the hole injection layers 32, which are common layers, are not formed by separately coating the first to third resonator structures (R, G, B), but formed simultaneously with one step. The film thickness can be adjusted by an application quantity of the liquid material, for example. Furthermore, the hole transport layer 33 is formed in a similar manner. Note however that a coating method for the hole injection layer 32 and the hole transport layer 33 is not limited to an ink jet method, and it may be a spraying method, a spin coat method, a dip method, a die coat method, or the like, for example. Moreover, if needed, it is possible to perform an insoluble treatment for a liquid material of the green light-emitting layer 31G and the blue light-emitting layer 31B to be applied in the next step.

Next, as shown in step 130 in FIG. 4, a liquid material of the green light-emitting layer 31G is applied within areas where the respective resonator structures (R, G, B) are formed, which are partitioned by the partition walls 6, by using an ink jet nozzle or the like, for example, and heated or irradiated with light to form a film. The blue light-emitting layer 31B is formed in a similar manner to the formation of the green light-emitting layer 31G. Moreover, the optical path length adjusting layer 35 is formed by a coating method in a similar manner to the formation of the hole transport layer 33. Although the green light-emitting layer 31G, the blue light-emitting layer 31B, and the optical path length adjusting layer 35 are formed by separately coating the first to third resonator structures (R, G, B) as described above, the film formation order is not particularly limited thereto.

Next, as shown in step 140 in FIG. 4, the red common layer 31R is formed by a vapor deposition method or a laser ablation method, for example.

Here, the red common layers 31R, which are common layers, are preferably formed simultaneously with one step in the resonator structures R, G, and B, not being formed with different steps for the resonator structures R, G, and B, respectively.

Next, as shown in step 150 in FIG. 4, the electron transport layer 34 is formed by using a vapor deposition method, for example. The electron transport layers 34, which are common layers, are preferably formed simultaneously with one step, not being formed by separately coating the first to third resonator structures (R, G, B).

Next, as shown in step 160 in FIG. 4, the cathode 4 is formed by using a vapor deposition method, for example. The patterning of the cathode 4 can be performed by using a mask such as a metal mask, or by utilizing the bank shape of the partition wall 6. In a case of a passive type, for example, the cathode can be patterned in a stripe shape. On the other hand, in a case of an active type, for example, the cathode can be made as what is called a whole electrode without performing patterning.

Finally, as shown in step 170 in FIG. 4, the sealing layer 5 is formed by using a plasma CVD method or the like under an inert gas atmosphere.

Through the steps described above, the RGB light-emitting elements shown in FIG. 1 can be manufactured. Note that although the illustration thereof is omitted, a display area formed by a number of RGB light-emitting elements may be covered with a second substrate (cover member), and the internal space thereof may be filled with an inert gas or an inert fluid.

According to the above-described embodiment, a display device with a display area formed by RGB light-emitting elements is configured such that the RGB light-emitting elements include resonator structures (R, G, B), and the red light-emitting layer 31R is disposed as a common layer in each of the light-emitting functional layers of the RGB light-emitting elements in order to reduce the number of separately coating steps. As a result, it is possible to suppress a reduction in color purity of green light and blue light outputted from the second resonator structure G and the third resonator structure B. That is, it is possible to obtain a display device capable of outputting red light, green light, and blue light with high color purity.

Furthermore, according to the above-described embodiment, although the green light-emitting layer 31G and the blue light-emitting layer 31B are formed by separately coating them with a coating method, the red light-emitting layers 31R, which are common layers, are formed not by separately coating them but with a film formation method other than a coating method. Therefore, one separately coating step can be omitted. As a result, a reduction in the manufacturing cost thereof can be achieved. Moreover, although a film formation accuracy of a coating method is said to be low in general, an increase in the product yield can be expected by forming the red common layer 31R with a method other than a coating method as in the present embodiment.

Furthermore, according to the above-described embodiment, by newly adding the optical path length adjusting layer 35, it is possible to set the resonator optical path length of the first resonator structure R to a preferable distance even if a film thickness of the red light-emitting layer 31R is made thin to be a common layer. Furthermore, by forming the optical path length adjusting layer 35 with a material having a hole or electron mobility higher than that of the red light-emitting layer 31R, there is obtained an advantage that it is possible to suppress a voltage increase in the first resonator structure R having the largest resonator optical path length.

Note that although the upper part and lower part reflective members are formed by the reflective electrode and the semi-transmissive electrode in the light-emitting element shown in FIG. 1, the present invention is not limited thereto. A reflective film different from an electrode may be formed. In such a case, an anode and a cathode on the side of the element having the reflective film different from an electrode are preferably transparent electrodes. Furthermore, it is not limited to the top emission structure, and a bottom emission structure may be employed by forming the lower part reflective member by a semi-transmissive electrode and forming the upper part reflective member by a reflective electrode. In such a case, a transparent material is used for the material of the substrate 1.

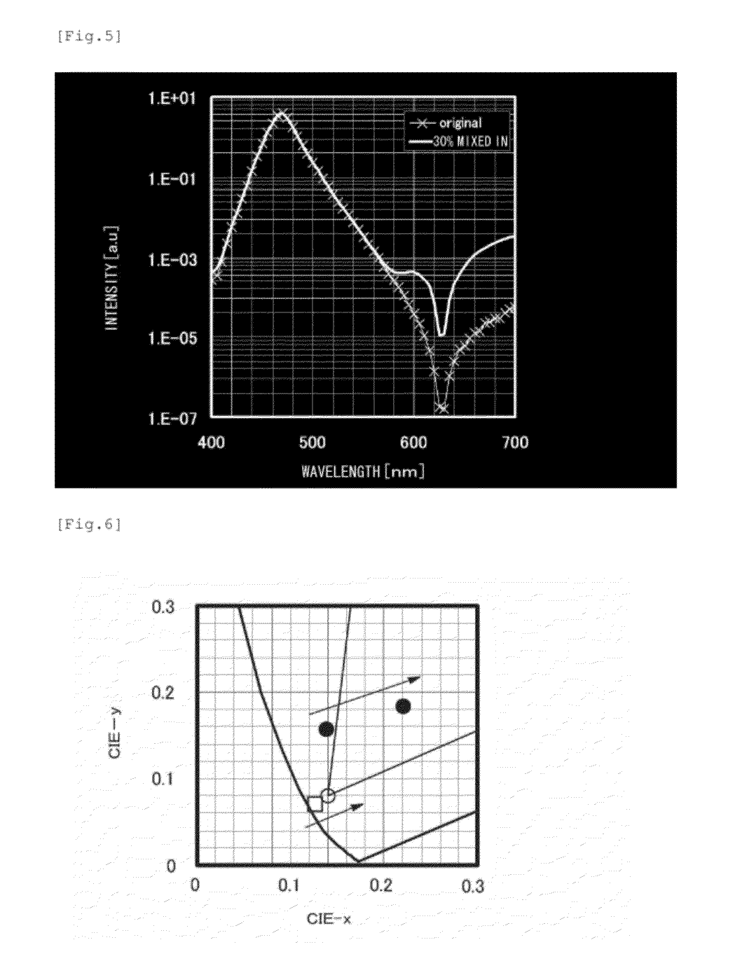

Next, with reference to FIGS. 5 to 8, a description will be made to simulation results about color purity of blue light and green light outputted from the first to third resonator structures (R, G, B) in which the red light-emitting layer 31R is a common layer. As seen from the simulation results, it can be further appreciated that the display device of the present embodiment can suppress a reduction in color purity.

FIG. 5 is a diagram showing emission characteristics of blue light in a resonator structure. It shows a spectrum in a case where no red common layer 31R is provided (that is, a case where no red light is mixed in) and a spectrum in a case where the red common layer 31R is provided (that is, a case where red light is mixed in). The mixed-in amount of red light is 30%. Moreover, the resonator optical path length is 195 nm. As can be seen from the simulation results of FIG. 5, about the third resonator structure B (blue pixel), an emission intensity in the vicinity of 470 nm, which corresponds to a wavelength range of blue light, barely changes even if a mixed-in amount of red light is 30%. That is, an influence from the mixing-in of red light is subtle.

FIG. 6 shows simulation results about a change in chromaticity if red emission is observed as impurity light in a blue pixel. The symbol ∘ in the figure shows NTSC. The symbol • (left) shows color purity only for blue emission and shows a change in a case where 30% red light is mixed with blue emission in a direction indicated by an arrow in the figure. The symbol □ shows a case where a resonance effect is generated in • (left). As can be seen from the results of FIG. 6, there is substantially no change in chromaticity in the configuration where a resonance effect is generated as in the present embodiment. Thus, with the configuration as in the present embodiment, it is possible to suppress a reduction in color purity for blue light even if red emission is mixed in as impurity light.

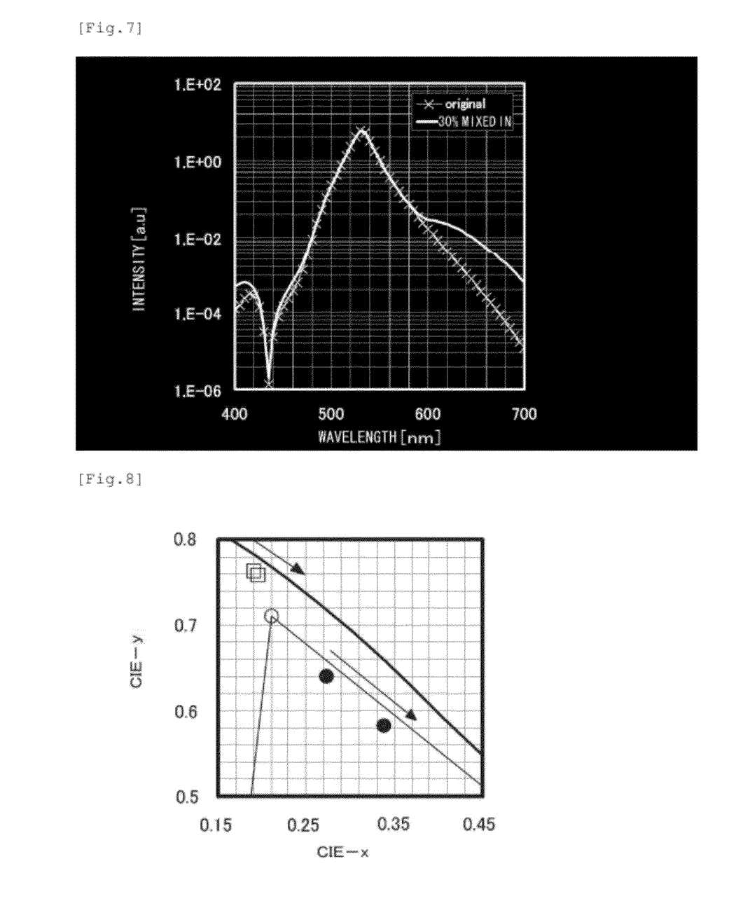

FIG. 7 is a diagram showing emission characteristics of green light in a resonator structure. It shows a spectrum in a case where no red common layer 31R is provided (that is, a case where no red light is mixed in) and a spectrum in a case where the red common layer 31R is provided (that is, a case where red light is mixed in). The mixed-in amount of red light is 30%. Moreover, the resonator optical path length is 240 nm. As can be seen from the simulation results of FIG. 7, also about the second resonator structure G (green pixel), an emission intensity in the vicinity of 530 nm, which corresponds to a wavelength range of green light, barely changes even if a mixed-in amount of red light is 30%. That is, an influence from the mixing-in of red light is subtle as with the case of a blue pixel.

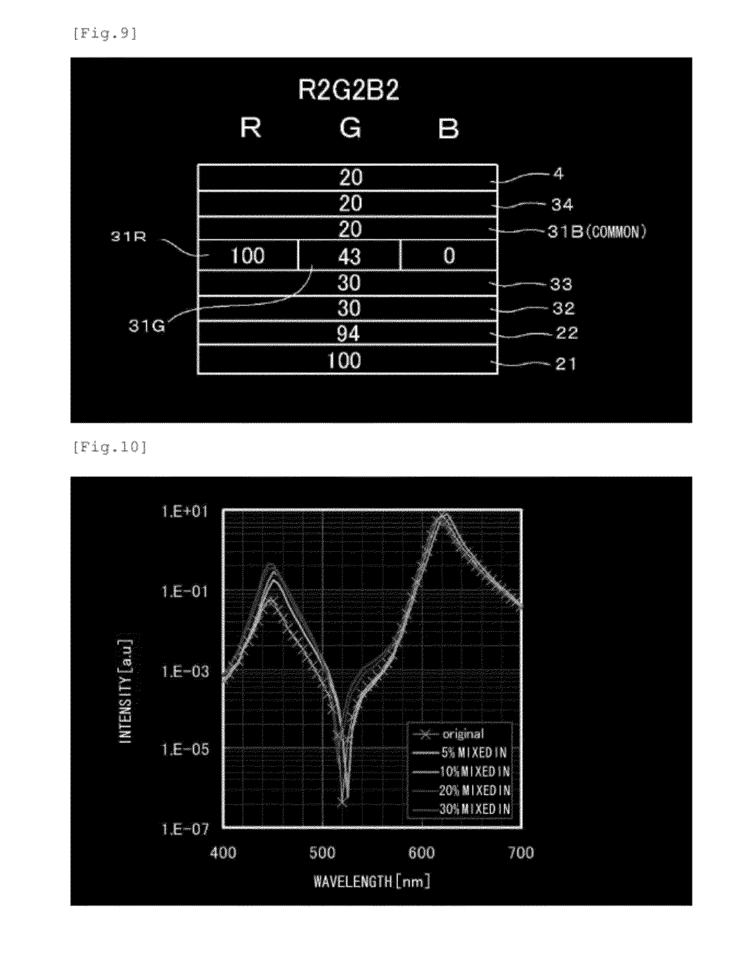

FIG. 8 shows simulation results about a change in chromaticity if red emission is observed as impurity light in a green pixel. The symbol ∘ in the figure shows NTSC. The symbol • (left) shows color purity only for green emission and shows a change in a case where 30% red light is mixed with green emission in a direction indicated by an arrow in the figure. The symbol □ shows a case where a resonance effect is generated in • (left). As can be seen from the results of FIG. 8, there is little change in chromaticity in the configuration where a resonance effect is generated as in the present embodiment. Thus, with the configuration as in the present embodiment, it is possible to suppress a reduction in color purity for green light even if red emission is mixed in as impurity light.

By way of comparison, there will be described simulation results in a case where the technique of Patent Literature 1 is employed and a blue light-emitting layer is made to be a common layer. FIG. 9 shows a hierarchical structure of RGB light-emitting elements used for the simulation.

FIG. 10 is a diagram showing emission characteristics of red light in the first resonator structure R. It shows a spectrum in a case where no blue common layer is provided (that is, a case where no blue light is mixed in) and spectra in a case where the blue common layer is provided (that is, a case where blue light is mixed in). The mixed-in amounts of blue light are 5%, 10%, 20%, and 30%. Moreover, the resonator optical path length is 300 nm. As can be seen from the simulation results of FIG. 10, as a mixed-in amount of blue light increases, an emission intensity in the vicinity of 470 nm, which corresponds to a wavelength range of blue light, increases. Furthermore, in a case of a red pixel, there is a characteristic such that a difference between an emission intensity in the vicinity of 470 nm and that in the vicinity of 620 nm is small. Thus, if the blue light-emitting layer is made to be a common layer in a resonator structure, an influence in the red pixel due to the mixing-in of blue light is large.

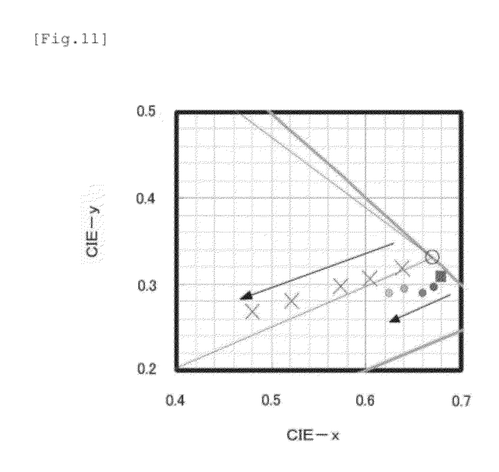

FIG. 11 shows simulation results about a change in chromaticity in a case where blue emission is observed as impurity light in a red pixel. The symbol ∘ in the figure shows NTSC. The symbol x (far right) shows color purity only for red emission and shows changes in a case where blue emission is mixed in an amount of 5%, 10%, 20%, and 30% in a direction indicated by an arrow. The symbol ▪ shows a case where a resonance effect is generated in x (far right). A plurality of the symbols • show cases where a resonance effect is generated in x emission (the second and subsequent ones from right) in a direction indicated by an arrow. As can be seen from the results of FIG. 11, if the blue light-emitting layer is made to be a common layer in a resonator structure, color purity is reduced in a red pixel due to the mixing in of blue emission.

As described above, according to the first and second embodiments, there are included: a first resonator structure having an upper part reflective member, a lower part reflective member, and a light-emitting functional layer disposed between the upper part reflective member and the lower part reflective member, the light-emitting functional layer including a red light-emitting layer which emits red light; a second resonator structure having an upper part reflective member, a lower part reflective member, and a light-emitting functional layer disposed between the upper part reflective member and the lower part reflective member, the light-emitting functional layer including a blue light-emitting layer which emits blue light; and a third resonator structure having an upper part reflective member, a lower part reflective member, and a light-emitting functional layer disposed between the upper part reflective member and the lower part reflective member, the light-emitting functional layer including a green light-emitting layer which emits green light. By configuring the red light-emitting layer to be a common layer provided in each of the light-emitting functional layers of the first to third resonator structures, it becomes possible to suppress a reduction in color purity for red (R), green (G), and blue (B).

Although the present invention has been described in detail based on the particular embodiments thereof, it is apparent to those skilled in the art that various substitutions, variations, modifications, and the like regarding its form and detail are possible without departing from the spirit and scope of the present invention as defined by the description of the claims. Therefore, it is to be understood that the scope of the present invention is not limited to the above-described embodiments and the accompanying drawings, and is determined based on the description of the claims and their equivalents.

### REFERENCE SIGNS LIST

1 substrate
2 anode
3 light-emitting functional layer
31R red light-emitting layer
31G green light-emitting layer
31B blue light-emitting layer
32 hole injection layer
33 hole transport layer
34 electron transport layer
35 optical path length adjusting layer
4 cathode
6 partition wall

1-11. (canceled)

12. A display device comprising:
a first resonator structure having an upper part reflective member, a lower part reflective member, and a light-emitting functional layer disposed between the upper part reflective member and the lower part reflective member, the light-emitting functional layer including a red light-emitting layer which emits red light;
a second resonator structure having an upper part reflective member, a lower part reflective member, and a light-emitting functional layer disposed between the upper part reflective member and the lower part reflective member, the light-emitting functional layer including a blue light-emitting layer which emits blue light; and
a third resonator structure having an upper part reflective member, a lower part reflective member, and a light-emitting functional layer disposed between the upper part reflective member and the lower part reflective member, the light-emitting functional layer including a green light-emitting layer which emits green light,
the display device characterized in that the red light-emitting layer is a common layer disposed in each of the light-emitting functional layers of the first to third resonator structures.

13. The display device according to claim 12, characterized in that the red light-emitting layers disposed as the common layers in the second and third resonator structures are disposed closer to a cathode than the blue light-emitting layer and the green light-emitting layer, and are formed from a material serving as a hole blocking layer and/or an electron transport layer in the second and third resonator structures.

14. The display device according to claim 12, characterized in that the red light-emitting layers are formed in the first to third resonator structures with the same film thickness, respectively.

15. The display device according to claim 12, characterized in that the red light-emitting layers disposed as the common layers in the second and third resonator structures are configured such that a mixed-in amount of red light is 30% or less with respect to blue light and/or green light.

16. The display device according to claim 15, characterized in that the red light-emitting layers have a thickness of 40 nm or less so as to mix in the red color in an amount of 30% or less.

17. The display device according to claim 12, characterized in that the first resonator structure further includes an optical path length adjusting layer in the light-emitting functional layer, the optical path length adjusting layer being formed from a material having a hole or electron mobility higher than that of the red light-emitting layer.

18. The display device according to claim 17, characterized in that the optical path length adjusting layer is disposed at a hierarchical position corresponding to the blue light-emitting layer and the green light-emitting layer in the second and third resonator structures, and is formed from a material having a hole mobility higher than that of the red light-emitting layer.

19. The display device according to claim 12, characterized in that the blue light-emitting layer and the green light-emitting layer are formed by separately coating them with a coating method, and the red light-emitting layers are light-emitting layers formed by a film formation method other than a coating method.

20. The display device according to claim 12, characterized in that
the light-emitting functional layer of the first resonator structure is a stacked structure of a hole injection layer and/or a hole transport layer, an optical path length adjusting layer, the red light-emitting layer, an electron transport layer and/or a hole blocking layer, and an electron injection layer,
the light-emitting functional layer of the second resonator structure is a stacked structure of a hole injection layer and/or a hole transport layer, the blue light-emitting layer, the red light-emitting layer, an electron transport layer and/or a hole blocking layer, and an electron injection layer,
the light-emitting functional layer of the third resonator structure is a stacked structure of a hole injection layer and/or a hole transport layer, the green light-emitting layer, the red light-emitting layer, an electron transport layer and/or a hole blocking layer, and an electron injection layer, and
the hole injection layer and/or the hole transport layer, the electron transport layer and/or the hole blocking layer, and the electron injection layer are common layers disposed in the first to third resonator structures, respectively.

21. The display device according to claim 20, characterized in that the hole injection layer and/or the hole transport layer are formed from a material insoluble to the material for the blue light-emitting layer and the green light-emitting layer or are subjected to insoluble treatment.

22. A method for manufacturing a display device, comprising:
forming lower part reflective members of first, second, and third resonator structures;
forming a light-emitting functional layer including a red light-emitting layer, which emits red light, on the lower part reflective member of the first resonator structure;
forming a light-emitting functional layer including a blue light-emitting layer, which emits blue light, on the lower part reflective member of the second resonator structure;
forming a light-emitting functional layer including a green light-emitting layer, which emits green light, on the lower part reflective member of the third resonator structure; and
forming upper part reflective members of the first, second, and third resonator structures, the method characterized in that
the blue light-emitting layer and the green light-emitting layer are formed in the second and third resonator structures by separately coating them with a coating method, and
the red light-emitting layer is formed in the first to third resonator structures with a film formation method other than the coating method as common layers disposed in the light-emitting functional layers of the first to third resonator structures, respectively.
